(19) United States
(12) Patent Application Publication
(10) Pub. No.: US 2010/0171181 A1
(43) Pub. Date: Jul. 8, 2010

(54) METHOD OF FORMING A SEMICONDUCTOR DEVICE HAVING AN EPITAXIAL SOURCE/DRAIN

(75) Inventors: Hwa Sung Rhee, Seongnam-si (KR); Myung Sun Kim, Hwaseong-si (KR); Ho Lee, Cheonan-si (KR); Hoi Sung Chung, Suwon-si (KR)

Correspondence Address: F. CHAU & ASSOCIATES, LLC, 130 WOODBURY ROAD, WOODBURY, NY, 11797, US

(73) Assignee: SAMSUNG ELECTRONICS CO., LTD., Gyeonggi-do (KR)

(21) Appl. No.: 12/640,944

(22) Filed: Dec. 17, 2009

(30) Foreign Application Priority Data
Jan. 7, 2009 (KR) 2009-0001008

(51) Int. Cl. H01L 27/06; H01L 21/8238

(52) U.S. Cl. 257/369; 438/221; 438/229; 257/E21.634; 257/E27.062; 257/E27.014

(57) ABSTRACT

A method of forming a semiconductor device includes forming a device isolation region in a silicon substrate to define an nMOS region and a pMOS region. A p-well is formed in the nMOS region and an n-well in the pMOS region. Gate structures are formed over the p-well and n-well, each gate structure including a stacked structure comprising a gate insulating layer and a gate electrode. A resist mask covers the nMOS region and exposes the pMOS region. Trenches are formed in the substrate on opposite sides of the gate structures of the pMOS region. SiGe layers are grown in the trenches of the pMOS region. The resist mask is removed from the nMOS region. Carbon is implanted to an implantation depth simultaneously on both the nMOS region and the pMOS region to form SiC on the nMOS region and SiGe on the pMOS region.

### CROSS-REFERENCE TO RELATED APPLICATION

This application claims priority to and the benefit of Korean Patent Application No. 2009-0001008, filed on Jan. 7, 2009, in the Korean Intellectual Property Office, the entire content of which is incorporated by reference herein.

### BACKGROUND

1. Technical Field

The present disclosure relates to semiconductor devices, and, more particularly, to semiconductor devices using epitaxial deposition.

2. Discussion of Related Art

In recent years the semiconductor industry has been striving to make semiconductors smaller and faster. However, continued scaling does not automatically make the scaled transistor faster because of scaling limitations, such as gate oxide (GOX) leakage current and short channel effect (i.e., the failure of normal operation as a result of making the gate length small). As such, improving performance with or without scaling has become an emerging requirement.

One approach for doing this for high performance CMOS devices has been to increase carrier (electron and/or hole) mobilities by introducing an appropriate strain into the silicon lattice. Germanium atoms are slightly larger than the lattice constant of silicon, i.e., 5.66 Å as compared to 5.43 Å, respectively, so SiGe on silicon exerts compressive strain on the silicon channel. Carbon has a much smaller lattice constant (3.65 Å), so silicon containing even a small amount of substitutional carbon exerts significant tensile stress on the channel.

A semiconductor device with strained transistors is proposed in U.S. Patent Publication No. 20070196989 wherein the performance improvement is sought in a semiconductor device having n-channel and p-channel transistors utilizing stress. However, the process involved is complex since the semiconductor substrate is made of a first semiconductor material; an n-channel field effect transistor is formed in the semiconductor substrate and having n-type source/drain regions made of a second semiconductor material different from the first semiconductor material; and a p-channel field effect transistor is formed in the semiconductor substrate having p-type source/drain regions made of a third semiconductor material different from the first semiconductor material, and the second and third semiconductor materials being different materials.

Another strained-silicon CMOS device is disclosed in U.S. Pat. No. 7,227,205. The '205 patent discloses producing a uniaxial strain in the device channel of the semiconductor device in a biaxially strained substrate surface by strain inducing lines, strain inducing wells or a combination thereof. However, the process involved is also complex. A substrate includes a strained semiconducting layer atop a strain inducing layer. The strain inducing layer produces a biaxial tensile strain in said strained semiconducting layer. A gate region includes a gate conductor atop a device channel portion of the strained semiconducting layer. The device channel portion separates source and drain regions adjacent the gate conductor. A strain inducing liner is positioned on the gate region. The strain inducing liner produces a uniaxial compressive strain to a device channel portion of the strained semiconducting layer underlying the gate region. The device channel portion of said strained semiconducting layer has a uniaxial compressive strain in a direction parallel to the length of said device channel portion, which is produced by the compressive strain inducing liner in conjunction with the biaxial tensile strained semiconducting layer.

Another strain technology approach involves etching out the source/drain area and replacing it with a lattice mismatched material such as epitaxial SiGe (eSiGe) in pFETs and epitaxial SiC (eSiC) in nFETs. Epitaxy is the process of growing a single-crystalline film of material on a single-crystalline substrate or wafer. Generally the crystal structure or orientation of the film is the same as that of the substrate. However, the concentration and/or type of intentionally introduced impurities is usually different in the film than in the substrate. Because of the epitaxial deposition technique, the germanium or carbon atoms substitutionally replace silicon atoms in the lattice, rather than forming the compound SiGe or SiC. See U.S. Pat. No. 7,303,949 for an example of an epitaxial deposition technique.

### SUMMARY

In accordance with exemplary embodiments of the present invention methods and apparatus for fabricating semiconductor devices using epitaxial deposition is provided.

In accordance with an exemplary embodiment, a method of forming a semiconductor device includes forming a device isolation region in a silicon substrate to define an nMOS region and a pMOS region. A p-well is formed in the nMOS region and an n-well in the pMOS region. Gate structures are formed over the p-well and n-well, each gate structure including a stacked structure having a gate insulating layer and a gate electrode. A resist mask covers the nMOS region and exposes the pMOS region. Trenches are formed in the substrate on opposite sides of the gate structures of the pMOS region. SiGe layers are grown in the trenches of the pMOS region. The resist mask is removed from the nMOS region. Carbon is implanted to an implantation depth simultaneously on both the nMOS region and the pMOS region to form SiC on the nMOS region and SiGeC on the pMOS region.

Growing SiGe layers may include overfilling the trenches of the pMOS region by a thickness above a top surface of the substrate.

Implanting carbon may include providing a layer of SiC having a thickness at the nMOS region of substantially the thickness overfilling the trenches of the pMOS region.

Growing SiGe layers may include filling the trenches to a top surface of the substrate with a first concentration of Ge, and overfilling the trenches to the thickness above the top surface with a second concentration of Ge that is higher than the first concentration.

Implanting carbon may include providing a layer of eSiGe having a thickness greater at the pMOS region than the thickness above the top surface.

The first concentration of Ge may be about 20% and the second concentration may be about 30%.

The thickness above the top surface may be the same as the implantation depth.

The concentration of carbon in SiC may be about 1.5%.

The SiC may be formed by implanting carbon into the Si substrate and regrowing with solid phase epitaxy.

A material from a metal group including Nickel may be formed on the pMOS by a silicidation process.

In accordance with an exemplary embodiment a semiconductor device includes a substrate. A device isolation region is between a p-well and an n-well in the substrate. A gate structure has a source region and a drain region on opposing sides above the p-well and the n-well, the source and drain regions in the p-well having SiC and the source and drain regions in the n-well having SiGe.

The semiconductor device may have a portion of the SiGeC layer that extends by a thickness above a top surface of the substrate.

The SiC layer may have a thickness substantially the same as a thickness of the portion of the SiGeC layer above the top surface of the substrate.

The thickness of the SiGeC layer may be greater than the thickness of the portion of the SiGeC layer that is above the top surface of the substrate, the SiGeC layer having a first concentration of Ge and the SiGe layer having a second concentration of Ge that is lower than the first concentration, the first concentration of Ge being about 30% and the second concentration being about 20%, the concentration of carbon in the SiC layer being about 1.5%.

The semiconductor device may be in a CMOS inverter.

The semiconductor device may be in an SRAM circuit having a CMOS device coupled between word lines and bit lines.

The semiconductor device may be in a NAND circuit having a CMOS device coupled between inputs and an output.

In accordance with an exemplary embodiment a semiconductor device includes a substrate. A device isolation region is between an nMOS region and a pMOS region in the substrate. A gate structure has a source region and a drain region on opposing sides above the nMOS region and the pMOS region, the source and drain regions in the nMOS region having an epitaxial grown eSiC layer and the source and drain regions in the pMOS region having an epitaxial grown eSiGeC layer.

A portion of the eSiGeC layer may extend by a thickness above a top surface of the substrate.

The eSiC layer may have a thickness substantially the same as a thickness of the portion of the eSiGeC layer above the top surface of the substrate.

A thickness of the eSiGeC layer may be greater than the thickness of the portion of the eSiGeC layer that is above the top surface of the substrate, the eSiGeC layer having a first concentration of Ge and the eSiGe layer having a second concentration of Ge that is lower than the first concentration.

The first concentration of Ge of the eSiGeC layer may be about 30% and the second concentration of Ge of the eSiGe layer is about 20%.

The concentration of carbon in the eSiC layer may be about 1.5%.

In accordance with an exemplary embodiment an electronic subsystem includes a host coupled to a memory system having a memory controller coupled to a memory device, the memory device having: a substrate, a device isolation region between a p-well and an n-well in the substrate, and a gate structure having a source region and a drain region on opposing sides above the p-well and the n-well, the source and drain regions in the p-well comprising a SiC layer and the source and drain regions in the n-well comprising a SiGeC layer.

The host may be a mobile device or a processing device having a processor.

The electronic subsystem may further include a wireless interface for communicating with a cellular device.

The electronic subsystem may further include a connector for removably connecting to a host system, wherein the host system is one of a personal computer, notebook computer, hand held computing device, camera, or audio reproducing device.

The wireless interface may communicate using a communication interface protocol of a third generation communication system, including one of code division multiple access (CDMA), global system for mobile communications (GSM), north American digital cellular (NADC), extended-time division multiple access (E-TDMA), wide band code division multiple access (WCDMA), or CDMA2000.

In accordance with an exemplary embodiment an electronic subsystem includes a printed circuit board supporting a memory unit, a device interface unit and an electrical connector, the memory unit having a memory that has memory cells arranged on the printed circuit board, the device interface unit being electrically connected to the memory unit and to the electrical connector through the printed circuit board, at least one of the memory unit and device interface unit comprising a semiconductor device having: a substrate, a device isolation region between a p-well and an n-well in the substrate; and a gate structure having a source region and a drain region on opposing sides above the p-well and the n-well, the source and drain regions in the p-well having a SiC layer and the source and drain regions in the n-well having a SiGeC layer.

In accordance with an exemplary embodiment of the present inventive concept, a method of forming a semiconductor device is provided. A first active region is separated from a second active region on a substrate. A first active region gate structure is formed on the first active region and a second active region gate structure is formed on the second active region. Trenches are formed in the first active region outside the first active region gate structure. A first active region epitaxial layer is grown in the trenches. Substitutional material is implanted in the second active region outside the second active region gate structure while at the same time substitutional material is implanted in the first active region epitaxial layer. A second active region epitaxial layer is grown in the second active region outside the second active region gate structure.

The first active region epitaxial layer may be grown in the trenches with material having a lattice constant larger than a lattice constant of the first active region material.

The first active region may be formed using silicon and the first active region epitaxial layer may be grown in the trenches using SiGe.

The substitutional material may have a lattice constant smaller than that of material in the second active region.

The second active region may include amorphized silicon. The substitutional material implanted may be carbon. The eSiC may be formed outside of the second active region gate structure by solid phase epitaxial growth.

The SiC may have a C concentration between a minimum of about 0.9% and a maximum of about 2%.

A metal silicide pattern may be further formed on the trenches and the metal silicide may be nickel silicide.

### BRIEF DESCRIPTION OF THE DRAWINGS

Exemplary embodiments of the present inventive concept will be more clearly understood from the following detailed description taken in conjunction with the accompanying drawings in which:

FIGS. 1a, 1b, 1c, 1d and 1e show a fabrication process and resultant semiconductor device according to an exemplary embodiment of the present inventive concept;

FIGS. 2a, 2b and 2c show a fabrication process and resultant semiconductor device according to another exemplary embodiment of the present inventive concept;

FIG. 3 depicts a resultant semiconductor device according to yet another exemplary embodiment of the present inventive concept;

FIG. 4 depicts a resultant semiconductor device according to still another exemplary embodiment of the present inventive concept;

FIG. 5 is a graph showing channel stress and mobility enhancement as a function of substitutional carbon;

FIG. 6 is a graph comparing sheet resistance as a function of post anneal temperature for a NiSix on SiGe:C process and for a NiSix on SiGe process; and

FIGS. 7, 8, 9, 10, 11 and 12 show various circuit and electronic subsystem diagrams which implement at least one of the exemplary embodiments of the present inventive concept described and shown in FIGS. 1a-1e, 2a-2c, 3 and 4.

### DETAILED DESCRIPTION OF THE EMBODIMENTS

Reference will now be made in detail to the exemplary embodiments, examples of which are illustrated in the accompanying drawings, wherein like reference numerals refer to the like elements throughout.

However, the present inventive concept may be embodied in many different forms and should not be construed as limited to the exemplary embodiments set forth herein. Rather, these embodiments are provided so that this disclosure will be thorough and complete, and will fully convey the scope of the inventive concept to those skilled in the art.

In the figures, the dimensions of layers and regions may be exaggerated for clarity. It will be understood that when a layer or element is referred to as being “on” another layer or element, it can be directly on the other layer or element, or intervening layers may also be present. Further, it will be understood that when a layer is referred to as being “under” another layer or element, it can be directly under the layer or element, or one or more intervening layers or elements may also be present. In addition, it will be understood that when a layer or an element is referred to as being “between” two layers or elements, it can be the only layer between the two layers or elements, or one or more intervening layers or elements may also be present. Like reference numerals refer to like elements throughout.

It will be understood that the order in which the steps of each fabrication method according to an exemplary embodiment of the present inventive concept disclosed in this disclosure are performed is not restricted to those set forth herein, unless specifically mentioned otherwise. Accordingly, the order in which the steps of each fabrication method according to an exemplary embodiment of the present inventive concept disclosed in this disclosure are performed can be varied.

It will be understood that, although the terms first, second, etc. may be used herein to describe various elements, these elements should not be limited by these terms. These terms are used to distinguish one element from another. For example, a first element could be termed a second element, and, similarly, a second element could be termed a first element, without departing from the scope of the present inventive concept. As used herein, the term “and/or” includes any and all combinations of one or more of the associated listed items.

It will be understood that when an element is referred to as “covering” another element, it can immediately cover the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

Unless otherwise defined, all terms (including technical and scientific terms) used herein have the same meaning as commonly understood by one of ordinary skill in the art to which the exemplary embodiments of the present inventive concept belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

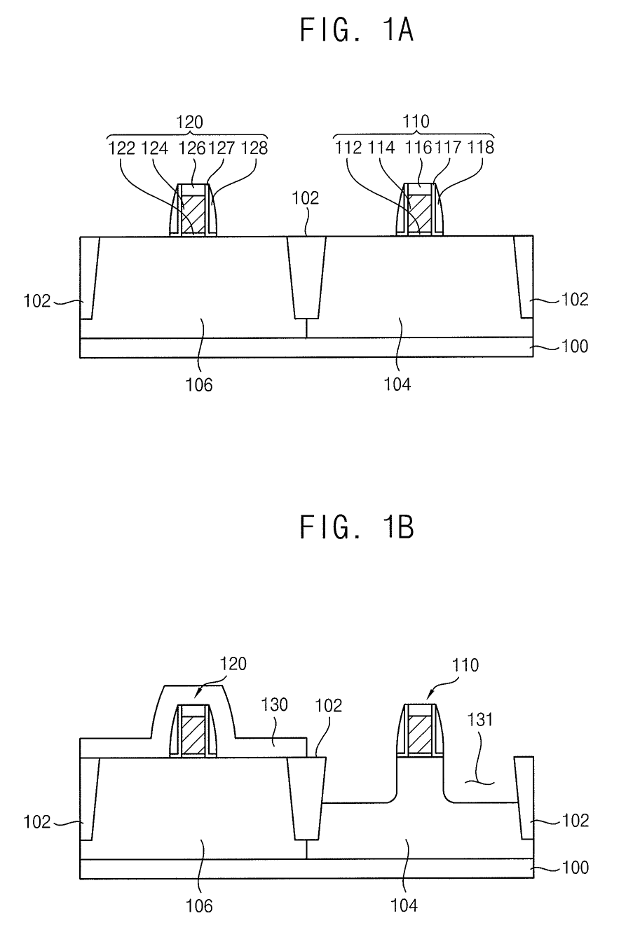

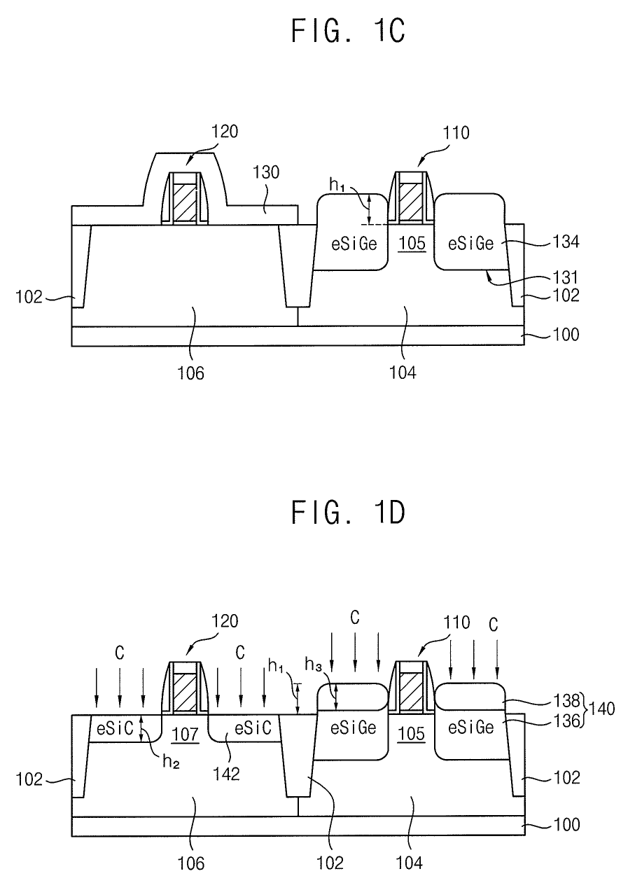

Referring now to FIGS. 1a-1e, there is shown a fabrication process using epitaxial deposition and the resultant semiconductor device according to an exemplary embodiment of the present inventive concept.

In FIG. 1a, device isolation region (STI) 102 separates a first active region 104 from a second active region 106 on substrate 100. In the present exemplary embodiment, the first active region 104 is an n-well and the second active region 104 is a p-well. Gate structure 110 includes insulator 112, gate conductive pattern 114, gate mask pattern 116, first spacer 117 and second spacer 118. Gate structure 120 includes insulator layer 122, gate conductive pattern 124, gate mask pattern 126, first spacer 127 and second spacer 128.

Next, in FIG. 1b resist mask 130 covers second gate structure 120 and second active region 106, exposing first active region 104 to allow trenches 131 to be formed by anisotropic etching using the first gate structure 110 and the device isolation region 102.

Then, in FIG. 1c epitaxial layers 134 are grown in trenches 131 by epitaxial growth of SiGe. The eSiGe completely fill trenches 131 and protrude above a surface of first active region 104 by a distance h₁. The eSiGe layers have a lattice constant larger than that of the silicon substrate. The resultant deformation in the eSiGe induces a compressive stress in channel 105 of first active region 104.

Referring to FIG. 1d, eSiC 142 is formed by implanting carbon (C) into an amorphized Si substrate to a depth h₂ using gate structure 120 of second active region 106 as a mask and regrowing it with solid phase epitaxy (SPE). SPE is typically done by first depositing a film of amorphous material on the crystalline substrate. The substrate is then heated to crystallize the film. The single crystal substrate serves as a template for crystal growth. At the same time, C ions are implanted into the eSiGe layer to a depth h₃ using gate structure 110 of first active region 104 as a mask. Lower eSiGe region 136 then becomes a lower portion of source/drain 140, while upper eSiGeC region 138 becomes an upper portion of source/drain 140. In accordance with this exemplary embodiment h1, h2 and h3 are substantially the same depth.

Referring to FIG. 1e, contacts are formed for the gates, sources and drains. To provide improved contact characteristics a silicidation process, which is an anneal process resulting in the formation of metal-Si alloy (silicide), is performed. According to an exemplary embodiment of the present inventive concept, the silicidation process is performed using transition metal silicides, including near-noble and refractory metal silicides such as titanium silicide, tungsten silicide, cobalt silicide, nickel silicide, etc. The metal silicides produce characteristics such as high corrosion resistance, oxidation resistance, good adhesion to and minimal reaction with SiO₂ and low interface stress. The metal silicides can be deposited by sputtering, chemical vapor deposition, or other like processes. For purposes of illustration, this exemplary embodiment and other embodiments are described which use nickel in the formation of source/drain contacts 142, 144 and gate contacts 148, 150 of the resulting semiconductor device.

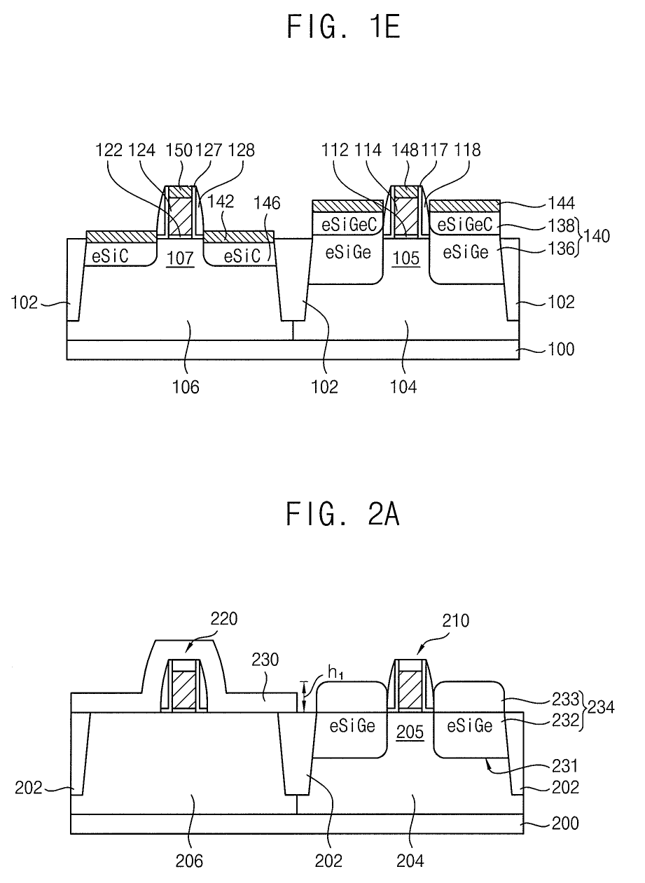

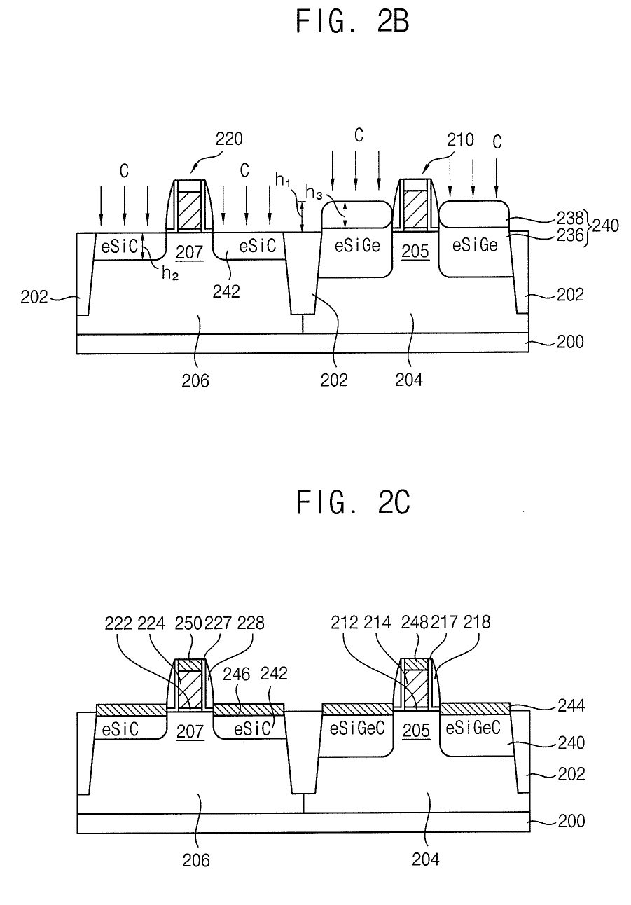

Referring now to FIGS. 2a, 2b and 2c another exemplary embodiment is provided. This exemplary embodiment is similar to the previous embodiment except that there is an additional process in which a protrusion portion, that is, the upper source/drain portion is removed.

Device isolation region 202 separates first active region 204 from second active region 206 on substrate 200. In the present exemplary embodiment first active region 204 is an n-well and second active region 206 is a p-well. Gate structure 210 includes insulator 212, gate conductive pattern 214, gate mask pattern 216, first spacer 217 and second spacer 218. Gate structure 220 includes insulator layer 222, gate conductive pattern 224, gate mask pattern 226, first spacer 227 and second spacer 228.

Resist mask 230 covers second gate structure 220 and second active region 206, exposing first active region 204 to allow trenches 231 to be formed by anisotropic etching using the first gate structure 210 and the device isolation region 202.

Epitaxial layers 234 are grown in trenches 231 by epitaxial growth of SiGe. The eSiGe completely fill trenches 231 and protrude above a surface of first active region 204 by a distance h₁. The eSiGe layers have a lattice constant larger than that of the silicon substrate. The resultant deformation in the eSiGe induces a compressive stress in channel 205 of first active region 204.

eSiC 242 is formed by implanting C into an amorphized Si substrate to a depth h₂ using gate structure 220 of second active region 206 as a mask and regrowing it with SPE. At the same time, C ions are implanted to a depth h₃ into eSiGe layer using gate structure 210 of first active region 204 as a mask forming upper eSiGe region 238 and lower eSiGe region 236. Upper eSiGe region 238 is then removed by chemical-mechanical polishing (CMP), etching, or the like. Lower eSiGe region 236 then becomes source/drain 240. A Ni-silicidation process is then performed to form source/drain contacts 244, 246 and gate contacts 248, 250 of the resulting semiconductor device.

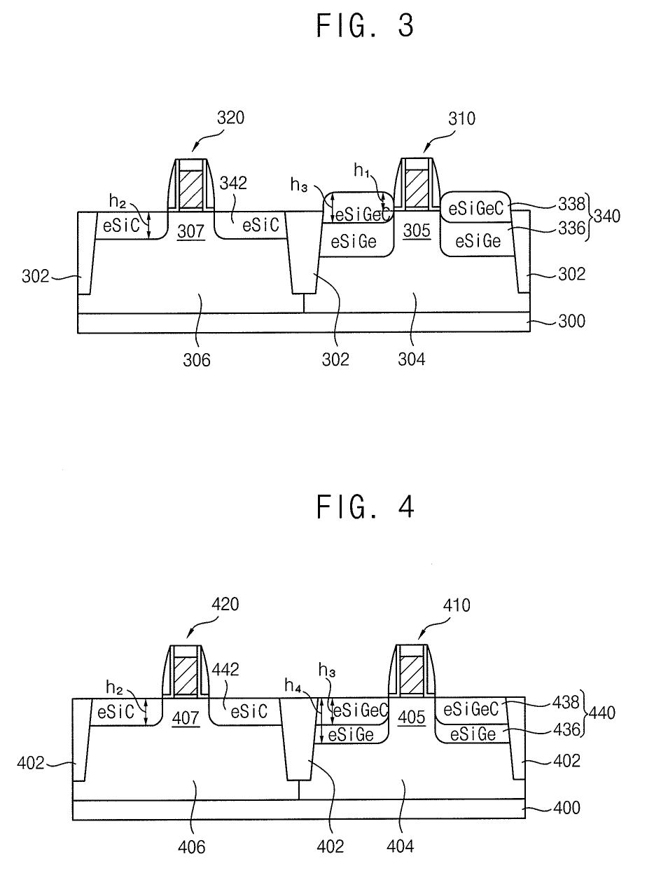

Referring now to FIG. 3, another exemplary embodiment is provided. This exemplary embodiment follows closely the process depicted in FIGS. 1a-1e and includes methodology which results in the implant depth h₃ being greater than the distance h₁ above the surface of the active region.

Device isolation region 302 separates first active region 304 from second active region 306 on substrate 300. In the present exemplary embodiment the first active region 304 is an n-well and the second active region 306 is a p-well. Gate structures 310, 320 each include an insulator, a gate conductive pattern, gate a mask pattern, first spacer and a second spacer. A resist mask covers the second gate structure and the nMOS region, exposing the pMOS region to allow the trenches to be formed by anisotropic etching using the first gate structure 310 and the device isolation region 302.

The epitaxial layers are grown in the trenches by epitaxial growth of SiGe. The eSiGe completely fill the trenches and protrude above a surface of first active region 304 by a distance h₁. The eSiGe layers have a lattice constant larger than that of the silicon substrate. The resultant deformation in the eSiGe induces a compressive stress in channel 305 of first active region 304.

The eSiC is formed by implanting C into an amorphized Si substrate to a depth h₂ using gate structure 320 of second active region 306 as a mask and regrowing it with SPE. At the same time, C ions are implanted to a depth h₃ using gate structure 310 of first active region 304 as a mask. Lower eSiGe region 336 then becomes a lower portion of source/drain 340, while upper eSiGeC region 338 becomes an upper portion of source/drain 340. In accordance with the exemplary embodiment the depth h₃ is greater than the distance h₁. A Ni-silicidation process (not shown) is then performed to form the source/drain contacts and the gate contacts of the resulting semiconductor device.

Referring now to FIG. 4, another exemplary embodiment is provided. This exemplary embodiment follows closely the process depicted in FIGS. 1a-1e and includes methodology which results in an upper source/drain being embedded in the substrate, not protruded from the substrate.

Device isolation region 402 separates first active region 404 from second active region 406 on substrate 400. In the present exemplary embodiment first active region 404 is an n-well and second active region 406 is a p-well. Gate structures 410, 420 each include an insulator, a gate conductive pattern, gate a mask pattern, first spacer and a second spacer. A resist mask covers the second gate structure and the nMOS region, exposing the pMOS region to allow the trenches to be formed by anisotropic etching using the first gate structure 410 and the device isolation region 402.

The epitaxial layers are grown in the trenches by epitaxial growth of SiGe. The eSiGe completely fill the trenches to a depth h₄ but do not protrude above a surface of first active region 404. The eSiGe layers have a lattice constant larger than that of the silicon substrate. The resultant deformation in the eSiGe induces a compressive stress in channel 405 of first active region 404.

The eSiC is formed by implanting C into an amorphized Si substrate to a depth h₂ using gate structure 420 of second active region 406 as a mask and regrowing it with SPE. At the same time, C ions are implanted to a depth h₃ in the eSiGe layer using gate structure 410 of first active region 404 as a mask. Lower eSiGe region 436 then becomes a lower portion of source/drain 440, while upper eSiGe region 438 becomes an upper portion of source/drain 440. A Ni-silicidation process (not shown) is then performed to form the contacts source/drain contacts and the gate contacts of the resulting semiconductor device.

In the exemplary embodiment where h₃=h₁, the concentration of Ge in the implanted region of the eSiGeC is the same as the concentration of Ge in the non-implanted region of the eSiGe. However, in the exemplary embodiment where h₃>h₁ the concentration of Ge in the implanted region of the eSiGeC is higher than the non-implanted region of the eSiGe, e.g., 30% Ge in the implanted region as compared to 20% Ge in the non-implanted region. In the exemplary embodiment where upper source/drain is embedded in the substrate and not protruded from the substrate, the concentration of Ge in the implanted region of the eSiGeC is also higher than the non-implanted region of the eSiGe, e.g., about 30% Ge in the implanted region as compared to about 20% Ge in the non-implanted region.

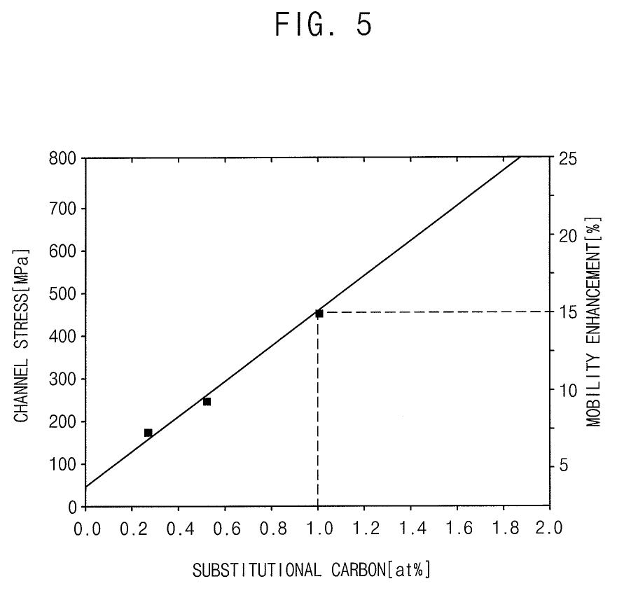

Referring now to FIG. 5, there is depicted a graph showing channel stress and mobility enhancement as a function of substitutional carbon. As discussed above, performance of high performance CMOS devices can be improved when there is an increase in carrier (electron and/or hole) mobilities. As can be seen in FIG. 5, as the percentage of C increases both the channel stress and the percentage of mobility enhancement increase. In an exemplary embodiment the SiC can have a C concentration between a minimum of about 0.9% and a maximum of about 2%. Having a C concentration greater than about 2% becomes impractical because of limited solid solubility of C in Si. In an exemplary embodiment, about 1% C can provide about 15% mobility enhancement.

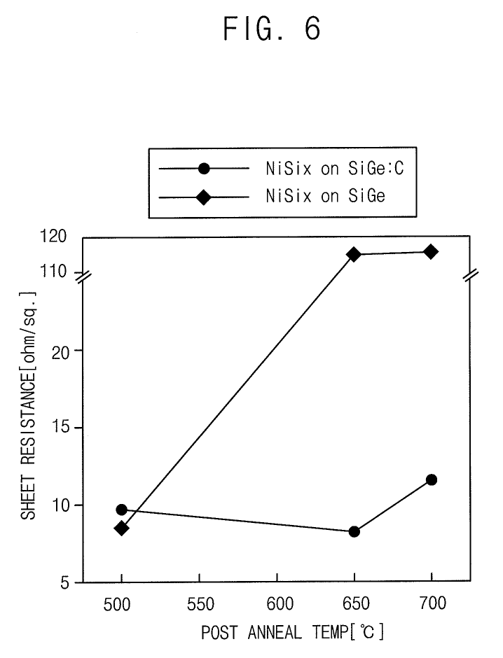

Referring now to FIG. 6, there is depicted a graph comparing sheet resistance as a function of post anneal temperature for Ni Six on SiGe:C and NiSix on SiGe. As can be seen there is a lower sheet resistance as a function of post anneal temperature when C is used with Ni as compared with C not being used. As such, there is improved thermal stability in the Ni-silicidation process when C is used with Ni to form the source/drain and gate contacts.

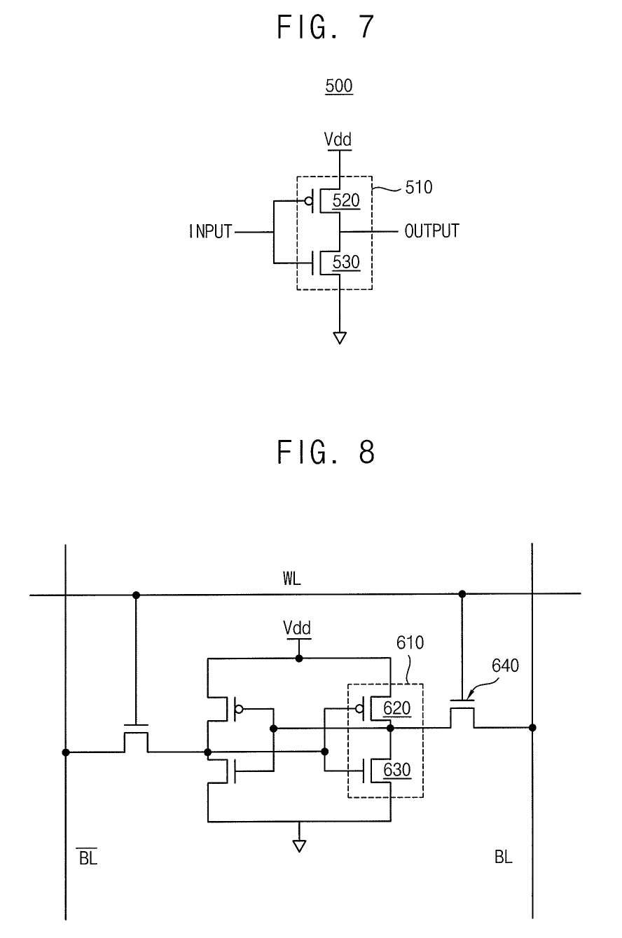

Referring now to FIGS. 7-12, there is depicted various circuit and electronic subsystem diagrams, each of which may implement at least one of the exemplary embodiments described above.

FIG. 7 shows CMOS inverter 500, having an input and output coupled to CMOS structure 510 which contains pMOS portion 520 an nMOS portion 530. The digital inverter is considered the basic building block for all digital electronics. Memory (1 bit register) is built as a latch by feeding the output of two serial inverters together. Multiplexers, decoders, state machines, and other sophisticated digital devices all rely on the basic inverter. In digital logic, an inverter or NOT gate is a logic gate which implements logical negation. The non-ideal transition region behavior of the CMOS inverter makes it useful in analog electronics as the output stage of an operational amplifier. The inverter circuit outputs a voltage representing the opposite logic-level to its input. Inverters can be constructed using two complimentary transistors in the CMOS configuration as depicted in FIG. 7. This configuration greatly reduces power consumption since one of the transistors is always off in both logic states. Processing speed can also be improved due to the relatively low resistance compared to the nMOS-only or pMOS-only type devices. Inverters can also be constructed with Bipolar Junction Transistors (BJT) in either a resistor-transistor logic (RTL) or a transistor-transistor logic (TTL) configuration. Therefore, by implementing the CMOS inverter circuit in accordance with at least one exemplary embodiment of the present inventive concept, the fundamental CMOS inverter circuit fabricated using epitaxial deposition has reduced complexity and improved fabrication speed.

FIG. 8 shows a CMOS static random access memory (SRAM) circuit having CMOS circuit 610 with pMOS portion 620 and nMOS portion 630 coupled to transistor 640. The SRAM is a type of semiconductor memory that does not need to be periodically refreshed. Each bit in an SRAM is stored on four transistors that form two cross-coupled inverters as shown in FIG. 8. This storage cell has two stable states which are used to denote 0 and 1. Two additional access transistors serve to control the access to a storage cell during read and write operations. The power consumption of SRAM varies widely depending on how frequently it is accessed. Many categories of industrial and scientific subsystems and automotive electronics contain SRAMs. Some are also embedded in practically all modern appliances, toys, etc that implements an electronic user interface. Several megabytes may be used in electronic products such as digital cameras, cell phones, synthesizers, etc. SRAMs are also used in personal computers, workstations, routers and peripheral equipment, internal CPU caches, external burst mode SRAM caches, hard disk buffers and router buffers, LCD screens and printers also normally employ static RAM to hold the image displayed (or to be printed). Small SRAM buffers are also found in CDROM and CDRW drives, usually 256 kB or more are used to buffer track data, which is transferred in blocks instead of as single values. The same applies to cable modems and similar equipment connected to computers. Therefore, by implementing the CMOS SRAM circuit in accordance with at least one exemplary embodiment of the present inventive concept, the CMOS SRAM circuit fabricated using epitaxial deposition has reduced complexity and improved fabrication speed.

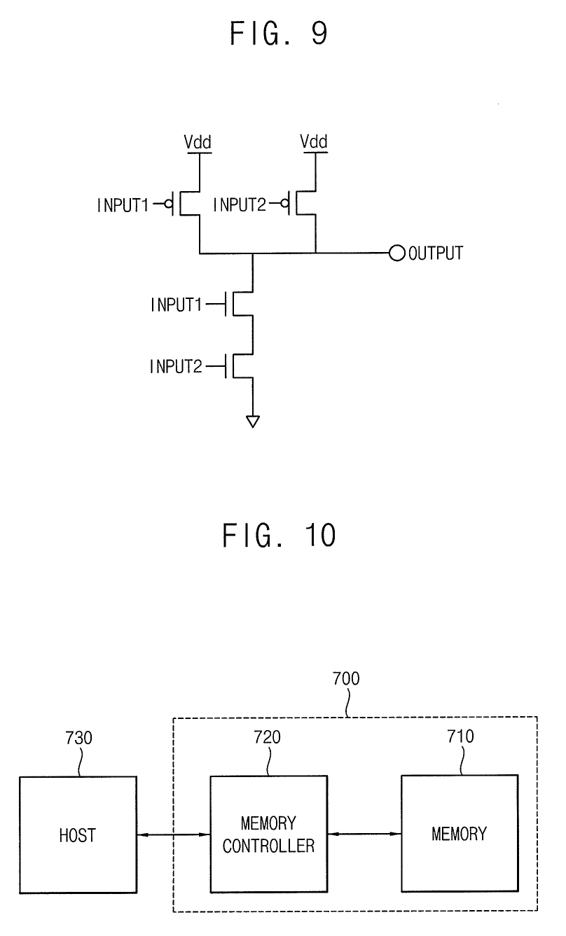

FIG. 9 shows a CMOS NAND circuit. Those skilled in the art will appreciate that the NAND gate is the easiest to manufacture, and also has the property of functional completeness. That is, any other logic function (AND, OR, etc.) can be implemented using only NAND gates. An entire processor can be created using NAND gates alone. Therefore, by implementing the NAND circuit in accordance with at least one exemplary embodiment of the present inventive concept, the NAND circuit fabricated using epitaxial deposition has reduced complexity and improved fabrication speed.

Referring now to FIGS. 10-12, various electronic subsystems are depicted.

FIG. 10 shows an electronic subsystem which includes a semiconductor device according to at least one exemplary embodiment of the present inventive concept. Electronic subsystem 700 includes a memory controller 720 and a memory 710, either of which may have a structure according to at least one exemplary embodiment of the present inventive concept. The memory controller 720 controls the memory device 710 to read or write data from/into the memory 710 in response to a read/write request of a host 730. The memory controller 720 may include an address mapping table for mapping an address provided from the host 730 (e.g., mobile devices or computer systems) into a physical address of the memory device 710.

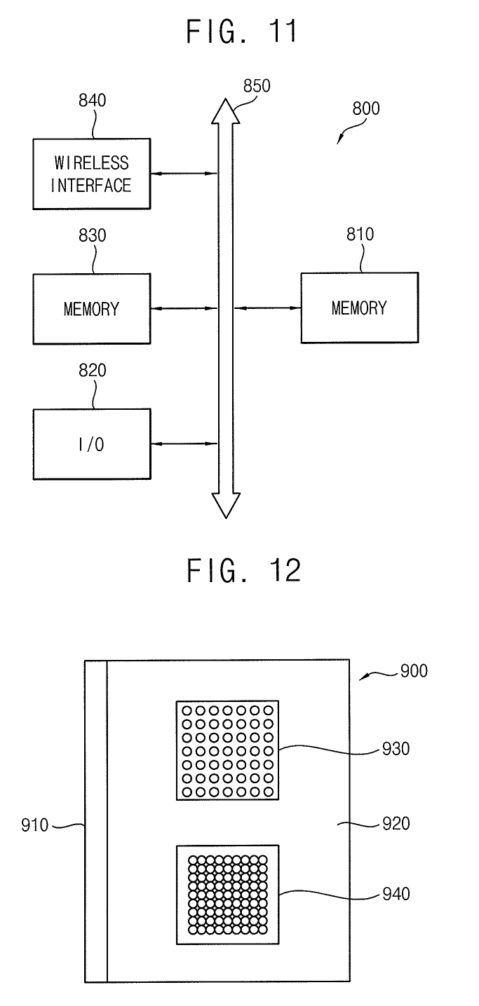

Referring to FIG. 11, an electronic subsystem including a semiconductor device according to at least one exemplary embodiment of the present inventive concept will now be described. Electronic subsystem 800 may be used in a wireless communication device (e.g., a personal digital assistant, a laptop computer, a portable computer, a web tablet, a wireless telephone, a mobile phone and/or a wireless digital music player.) or in any device capable of transmitting and/or receiving information via wireless environments.

The electronic subsystem 800 includes a controller 810, an input/output (I/O) device 820 (e.g., a keypad, a keyboard, and a display), a memory 830, and a wireless interface 840, each device being coupled to a communication bus 850 and may have a structure according to at least one exemplary embodiment of the present inventive concept. The controller 810 may include at least one of a microprocessor, a digital signal processor, or a similar processing device. The memory 830 may be used to store commands executed by the controller 810, for example. The memory 830 may be used to store user data. The electronic system 800 may utilize the wireless interface 840 to transmit/receive data via a wireless communication network. For example, the wireless interface 840 may include an antenna and/or a wireless transceiver. The electronic system 800 according to exemplary embodiments may be used in a communication interface protocol of a third generation communication system, e.g., code division multiple access (CDMA), global system for mobile communications (GSM), north American digital cellular (NADC), extended-time division multiple access (E-TDMA) and/or wide band code division multiple access (WCDMA), CDMA2000.

Referring to FIG. 12, an electronic subsystem including a semiconductor device according to at least one exemplary embodiment of the present inventive concept will now be described. Electronic subsystem 900 may be a modular memory device and includes a printed circuit board 920. The printed circuit board 920 may form one of the external surfaces of the modular memory device 900. The printed circuit board 920 may support a memory unit 930, a device interface unit 940, and an electrical connector 910.

The memory unit 930 may have a various data storage structures, including at least one exemplary embodiment of the present inventive concept, and may include a three-dimensional memory array and may be connected to a memory array controller. The memory array may include the appropriate number of memory cells arranged in a three-dimensional lattice on the printed circuit board 920. The device interface unit 940 may be formed on a separated substrate such that the device interface unit 940 may be electrically connected to the memory unit 930 and the electrical connector 910 through the printed circuit board 920. Additionally, the memory unit 930 and the device interface unit 940 may be directly mounted on the printed circuit board 920. The device interface unit 940 may include components necessary for generating voltages, clock frequencies, and protocol logic.

Therefore, by implementing any one of the above-described electronic subsystems with components in accordance with at least one exemplary embodiment of the present inventive concept, the components fabricated using epitaxial deposition has reduced complexity and improved fabrication speed.

In accordance with at least one of the exemplary embodiments depicting the fabrication processes additional masking does not need to be added for semiconductor devices having eSiGe for pMOS and eSiC for nMOS. Also, the thermal stability of Ni-silicide on eSiGe is upgraded upon the addition of carbon ions.

While exemplary embodiments have been particularly shown and described, it will be understood that various changes in form and details may be made therein without departing from the spirit and scope of the following claims.

What is claimed is:

1. A method of forming a semiconductor device comprising:
forming a device isolation region in a silicon substrate to define an nMOS region and a pMOS region;
forming gate structures over the nMOS region and the pMOS region, each gate structure including a stacked structure comprising a gate insulating layer and a gate electrode;
forming a resist mask covering the nMOS region and exposing the pMOS region;
forming trenches in the substrate on opposite sides of the gate structures of the pMOS region;
growing SiGe layers in the trenches of the pMOS region;
removing the resist mask from the nMOS region; and
implanting carbon to an implantation depth simultaneously on both the nMOS region and the pMOS region to form SiC on the nMOS region and SiGeC on the pMOS region.

2. The method of claim 1, wherein the step of growing SiGe layers comprises overfilling the trenches of the pMOS region by a thickness above a top surface of the substrate.

3. The method of claim 2, wherein the step of implanting carbon comprises providing a layer of SiC having a thickness at the nMOS region of substantially the thickness overfilling the trenches of the pMOS region.

4. The method of claim 2, wherein the step of growing SiGe layers comprises filling the trenches to a top surface of the substrate with a first concentration of Ge, and overfilling the trenches to the thickness above the top surface with a second concentration of Ge that is higher than the first concentration.

5. The method of claim 4, wherein the step of implanting carbon comprises providing a layer of eSiGe having a thickness greater at the pMOS region than the thickness above the top surface.

6. The method of claim 4, wherein the first concentration of Ge is about 20% and the second concentration is about 30%.

7. The method of claim 2, wherein the thickness above the top surface is the same as the implantation depth.

8. The method of claim 1, wherein the concentration of carbon in SiC is about 1.5%.

9. The method of claim 1, wherein SiC is formed by implanting carbon into the Si substrate and regrowing with solid phase epitaxy.

10. The method of claim 1, further comprising forming on the SiC and on the SiGeC a material from a metal group including Nickel by a silicidation process.

11. A semiconductor device, comprising:
a substrate;
a device isolation region between a p-well and an n-well in the substrate; and
a gate structure having a source region and a drain region on opposing sides above the p-well and the n-well, the source and drain regions in the p-well comprising a SiC layer and the source and drain regions in the n-well comprising a SiGeC layer.

12. The semiconductor device of claim 11, wherein a portion of the SiGeC layer extends by a thickness above a top surface of the substrate.

13. The semiconductor device of claim 12, wherein the SiC layer has a thickness substantially the same as a thickness of the portion of the SiGeC layer above the top surface of the substrate.

14. The semiconductor device of claim 12, wherein a thickness of the SiGeC layer is greater than the thickness of the portion of the SiGeC layer that is above the top surface of the substrate, the SiGeC layer having a first concentration of Ge and the SiGe layer having a second concentration of Ge that is lower than the first concentration.

15. The semiconductor device of claim 14, wherein the first concentration of Ge is about 30% and the second concentration is about 20%.

16. The semiconductor device of claim 11, wherein the concentration of carbon in the SiC layer is about 1.5%.

17. The semiconductor device of claim 11, wherein the semiconductor device is in a CMOS inverter.

18. The semiconductor device of claim 11, wherein the semiconductor device is in an SRAM circuit comprising a CMOS device coupled between word lines and bit lines.

19. The semiconductor device of claim 11, wherein the semiconductor device is in a NAND circuit comprising a CMOS device coupled between inputs and an output.

20. A semiconductor device, comprising:
a substrate;
a device isolation region between an nMOS region and a pMOS region in the substrate; and
a gate structure having a source region and a drain region on opposing sides above the nMOS region and the pMOS region, the source and drain regions in the nMOS region comprising an epitaxial grown eSiC layer and the source and drain regions in the pMOS region comprising an epitaxial grown eSiGeC layer.

21. The semiconductor device of claim 20, wherein a portion of the eSiGeC layer extends by a thickness above a top surface of the substrate.

22. The semiconductor device of claim 21, wherein the eSiC layer has a thickness substantially the same as a thickness of the portion of the eSiGeC layer above the top surface of the substrate.

23. The semiconductor device of claim 21, wherein a thickness of the eSiGeC layer is greater than the thickness of the portion of the eSiGeC layer that is above the top surface of the substrate, the eSiGeC layer having a first concentration of Ge and the eSiGe layer having a second concentration of Ge that is lower than the first concentration.

24. The semiconductor device of claim 23, wherein the first concentration of Ge of the eSiGeC layer is about 30% and the second concentration of Ge of the eSiGe layer is about 20%.

25. The semiconductor device of claim 20, wherein the concentration of carbon in the eSiC layer is about 1.5%.

26. The semiconductor device of claim 20, wherein the semiconductor device is in a CMOS inverter.

27. The semiconductor device of claim 20, wherein the semiconductor device is in an SRAM circuit comprising a CMOS device coupled between word lines and bit lines.

28. The semiconductor device of claim 20, wherein the semiconductor device is in a NAND circuit comprising a CMOS device coupled between inputs and an output.

29. A method of forming a semiconductor device, comprising:
separating a first active region from a second active region on a substrate;
forming a first active region gate structure on the first active region and a second active region gate structure on the second active region;
forming trenches in the first active region outside the first active region gate structure;
growing a first active region epitaxial layer in the trenches;
implanting substitutional material in the second active region outside the second active region gate structure while at the same time implanting substitutional material in the first active region expitaxial layer; and
growing a second active region epitaxial layer in the second active region outside the second active region gate structure.

30. The method of claim 29, wherein the first active region epitaxial layer is grown in the trenches with material having a lattice constant larger than a lattice constant of the first active region material.

31. The method of claim 30, wherein the first active region is formed using silicon and the first active region epitaxial layer is grown in the trenches using SiGe.

32. The method of claim 29, wherein the substitutional material has a lattice constant smaller than that of material in the second active region.

33. The method of claim 29, wherein the second active region comprises amorphized silicon, the substitutional material implanted is carbon, and eSiC is formed outside of the second active region gate structure by solid phase epitaxial growth.

34. The method of claim 33, wherein the SiC has a C concentration between a minimum of about 0.9% and a maximum of about 2%.

35. The method of claim 29, further including forming a metal silicide pattern on the trenches.

36. The method of claim 35, wherein the metal silicide is nickel silicide.

37. An electronic subsystem comprising a host coupled to a memory system having a memory controller coupled to a memory device, the memory device comprising:
a substrate;
a device isolation region between a p-well and an n-well in the substrate; and
a gate structure having a source region and a drain region on opposing sides above the p-well and the n-well, the source and drain regions in the p-well comprising a SiC layer and the source and drain regions in the n-well comprising a SiGeC layer.

38. The electronic subsystem of claim 37, wherein the host is a mobile device or a processing device having a processor.

39. The electronic subsystem of claim 37, further comprising a wireless interface for communicating with a cellular device.

40. The electronic subsystem of claim 37, further comprising a connector for removably connecting to a host system, wherein the host system is one of a personal computer, notebook computer, hand held computing device, camera, or audio reproducing device.

41. The electronic device of claim 39, wherein the wireless interface communicates using a communication interface protocol of a third generation communication system, including one of code division multiple access (CDMA), global system for mobile communications (GSM), north American digital cellular (NADC), extended-time division multiple access (E-TDMA), wide band code division multiple access (WCDMA), or CDMA2000.

42. An electronic subsystem comprising a printed circuit board supporting a memory unit, a device interface unit and an electrical connector, the memory unit having a memory that has memory cells arranged on the printed circuit board, the device interface unit being electrically connected to the memory unit and to the electrical connector through the printed circuit board, at least one of the memory unit and device interface unit comprising a semiconductor device having:
a substrate;
a device isolation region between a p-well and an n-well in the substrate; and
a gate structure having a source region and a drain region on opposing sides above the p-well and the n-well, the source and drain regions in the p-well comprising a SiC layer and the source and drain regions in the n-well comprising a SiGeC layer.
